(19) United States
(12) Patent Application Publication
(10) Pub. No.: US 2025/0176393 A1
(43) Pub. Date: May 29, 2025

(54) DISPLAY PANEL AND DISPLAY DEVICE

(71) Applicants: Guangzhou Govisionox Technology Co., Ltd., Guangzhou (CN); HEFEI VISIONOX TECHNOLOGY CO., LTD., Hefei (CN); KunShan Go-Visionox Opto-Electronics Co., Ltd., Kunshan (CN)

(72) Inventors: Ying CAO, Guangzhou (CN); Yuan YAO, Guangzhou (CN); Mingsheng LI, Guangzhou (CN); Jinzhen HUANG, Guangzhou (CN); Chuanzhi XU, Guangzhou (CN)

(73) Assignees: Guangzhou Govisionox Technology Co., Ltd., Guangzhou (CN); HEFEI VISIONOX TECHNOLOGY CO., LTD., Hefei (CN); KunShan Go-Visionox Opto-Electronics Co., Ltd., Kunshan (CN)

(21) Appl. No.: 18/663,337

(22) Filed: May 14, 2024

(30) Foreign Application Priority Data
Nov. 24, 2023 (CN) 202311591948.4

(51) Int. Cl. H10K 59/35; H10K 59/122; H10K 59/131; H10K 59/40; H10K 59/80

(52) U.S. Cl. CPC H10K 59/353; H10K 59/122; H10K 59/131; H10K 59/40; H10K 59/873; H10K 59/8792

(57) ABSTRACT

The display panel has a display area and a non-display area. The display panel includes an array substrate, an isolation structure, a plurality of sub-pixels and a plurality of virtual pixels, and a touch component. The isolation structure is disposed on the array substrate. A plurality of isolation openings are defined on the isolation structure. At least one of the plurality of sub-pixels is located in the display area and includes a light-emitting structure and a first electrode stacked on the light-emitting structure. At least one of the plurality of virtual pixels is located in the non-display area and includes a first virtual electrode. At least a part of the touch component is located on a side of the first electrode away from the array substrate and a side of the first virtual electrode away from the array substrate.

### CROSS-REFERENCE TO RELATED APPLICATIONS

This application claims priority to Chinese Patent Application No. 202311591948.4, filed on Nov. 24, 2023 in the National Intellectual Property Administration of China, the contents of which are herein incorporated by reference in their entireties.

### TECHNICAL FIELD

The present disclosure relates to the field of display technologies, and in particular to a display panel and a display device.

### BACKGROUND

Due to the benefits like high image quality, power saving, thin body, broad applications, and etc., an organic light emitting diode (OLED) display device and a flat display device based on a light emitting diode (LED) or other technologies are widely applied in various consumer electronic products, such as a cellphone, a television, a laptop computer, a desktop computer or the like, thereby becoming the mainstream of display device.

However, a performance of the current OLED display product needs to be improved.

### SUMMARY OF THE DISCLOSURE

Some embodiments of the present disclosure provide a display panel and a display device.

In a first aspect, some embodiments of the present disclosure provide a display panel. The display panel has a display area and a non-display area. The display panel includes an array substrate, an isolation structure, a plurality of sub-pixels and a plurality of virtual pixels, and a touch component. The isolation structure includes a first isolation structure in the display area and a second isolation structure in the non-display area. The first isolation structure and the second isolation structure are both disposed on the array substrate and a plurality of isolation openings are defined on the first isolation structure and the second isolation structure. At least one of the plurality of sub-pixels is located in the display area and includes a light-emitting structure and a first electrode stacked on the light-emitting structure. The light-emitting structure is located in a corresponding one of the plurality of isolation openings in the first isolation structure. At least one of the plurality of virtual pixels is located in the non-display area and includes a virtual light-emitting portion and a first virtual electrode stacked on the virtual light-emitting portion. The virtual light-emitting portion is located in a corresponding one of the plurality of isolation openings in the second isolation structure. At least a part of the touch component is located on a side of the first electrode away from the array substrate and a side of the first virtual electrode away from the array substrate.

In a second aspect, some embodiments of the present disclosure provide a display device. The display device includes the display panel in any one of the embodiments mentioned above.

The embodiments of the present disclosure provide a display panel and a display device. The isolation structure of the display panel in the embodiments of the present disclosure includes a first isolation structure in the display area and a second isolation structure in the non-display area. The plurality of virtual pixels are additionally arranged in the non-display area, at least one of the plurality of virtual pixels includes a virtual light-emitting portion and a first virtual electrode stacked on the virtual light-emitting portion. The virtual light-emitting portion is located in a corresponding one of the plurality of isolation openings in the second isolation structure. The plurality of virtual pixels and the second isolation structure may be configured to shield a signal between the touch component and the array substrate in the non-display area. The plurality of isolation openings defined on the second isolation structure may further be configured to fully release remaining moisture from a lower film layer before an evaporation in order to avoid separating the film layer structures as a result of a swelling deformation caused by the moisture. Besides, during a preparation of the light-emitting structure, a light-emitting material deposited in a corresponding one of the plurality of isolation openings defined on second isolation structure forms the virtual light-emitting portion so that the virtual light-emitting portion is no longer required to be further removed in separate by means of etching or other methods, thereby simplifying the preparation method and improving a production efficiency.

### BRIEF DESCRIPTION OF THE DRAWINGS

In order to clearly illustrate the technical solutions in the present disclosure, the following briefly illustrates drawings associated with embodiments of the present disclosure. Obviously, the drawings described as follows are only for some embodiments of the present disclosure. For an ordinary skilled in the art, other drawings may be derived based on the following drawings without creative work.

FIG. 1 is a schematic top view of a display panel according to some embodiments of the present disclosure.

FIG. 2 is a schematic section view of a display panel according to some embodiments of the present disclosure.

FIG. 3 is a schematic section view of a display panel from another perspective according to some embodiments of the present disclosure.

FIG. 4 is a schematic partial top view of a display panel according to some embodiments of the present disclosure.

FIG. 5 is a schematic section view of a display panel according to some embodiments of the present disclosure.

FIG. 6 is a schematic section view of a display panel according to some embodiments of the present disclosure.

FIG. 7 is a schematic section view of a display panel according to some embodiments of the present disclosure.

FIG. 8 is a schematic partial top view of a display panel according to some embodiments of the present disclosure.

FIG. 9 is a schematic section view of a display panel according to some embodiments of the present disclosure.

FIG. 10 is a schematic section view of a display panel according to some embodiments of the present disclosure.

FIG. 11 is a schematic partial top view of a display panel according to some embodiments of the present disclosure.

FIG. 12 is a schematic section view of a display panel according to some embodiments of the present disclosure.

FIG. 13 is a schematic top view of a display panel according to some embodiments of the present disclosure.

FIG. 14 is a schematic partial top view of a display panel according to some embodiments of the present disclosure.

Reference numerals: display panel 100; display area AA; non-display area NA; light-transmitting aperture NA1; aperture bezel area NA2; display bezel area NA5; array substrate 10; base 11; drive circuit layer 12; drive circuit line 13; first recess 14; second recess 15; isolation structure 20; first isolation structure 21; second isolation structure 22; shielding structure 23; isolation opening 20a; support layer 24; masking layer 25; sub-pixel 30; second electrode E2; light-emitting structure 31; first electrode E1; virtual pixel 40; second virtual electrode C2; third virtual electrode C3; virtual light-emitting portion 41; first virtual electrode C1; pixel defining layer 50; pixel defining portion 51; pixel opening 52; touch component 60; first encapsulation layer 71; second encapsulation layer 72; bank 80; first bank 81; second bank 82; first sub-area NA3; second sub-area NA4; thin film transistor TFT; planarization layer 16.

### DETAILED DESCRIPTION

The implementations of the present disclosure are described in further detail with drawings and embodiments. The detailed description of the following embodiments and drawings are used to exemplarily illustrate the principles of the present disclosure, but may not limit the scope of the present disclosure, i.e., the present disclosure is not limited to the described embodiments.

In some display panels, due to a presence of an isolation structure, a precise mask plate may be eliminated during an evaporation of a light-emitting structure. However, during a preparation of sub-pixels of different colors, sub-pixels of a specific color are evaporated first on an entire side of a display panel, and then an etch process is applied to a pixel opening that is configured to set a sub-pixel on the display panel to have another color so that a cathode and a light-emitting structure of the sub-pixel to be set to have another color are removed. The above process is repeated afterward for each sub-pixel to be set to have another color in order to form the sub-pixels of different colors. The isolation structure is not disposed in a non-display area of the display panel, thus when the cathode of the sub-pixel to be set to have another color is removed, a cathode of the non-display area is removed by the etch process, thereby leading to an array substrate causing signal interference to a touch component and reducing a performance of the display panel.

The embodiments of the present disclosure provide a display panel. This display panel may be an OLED display panel or other types of display panel, such as a micro light emitting diode (Micro-LED) display panel or a quantum light emitting diode (QLED) display panel.

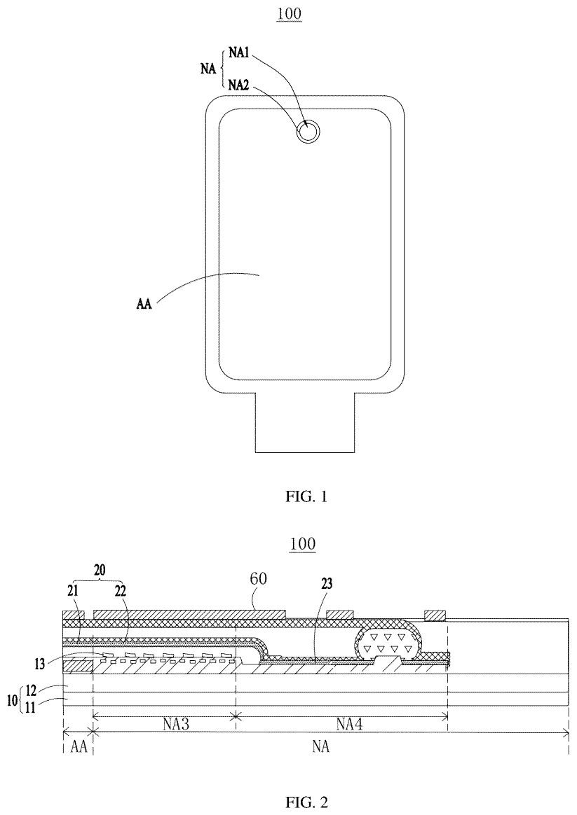

As illustrated in FIG. 1 to FIG. 4, a first aspect of the present disclosure provides a display panel 100 that includes a display area AA and a non-display area NA. The display panel 100 includes an array substrate 10, an isolation structure 20, a plurality of sub-pixels 30, a plurality of virtual pixels 40, and a touch component 60. The array substrate 10 includes a drive circuit layer 12. The isolation structure 20 includes a first isolation structure 21 in the display area AA and a second isolation structure 22 in the non-display area NA. The first isolation structure 21 and the second isolation structure 22 both are disposed on the array substrate 10. A plurality of isolation openings 20a are defined on both the first isolation structure 21 and the second isolation structure 22. At least one of the plurality of sub-pixels 30 is located in the display area AA and includes a light-emitting structure 31 and a first electrode E1 stacked on the light-emitting structure 31. The light-emitting structure 31 is located in a corresponding one of the plurality of isolation openings 20a in the first isolation structure 21. At least one of the plurality of virtual pixels 40 is located in the non-display area NA and includes a virtual light-emitting portion 41 and a first virtual electrode C1 stacked on the virtual light-emitting portion 41. The virtual light-emitting portion 41 is located in a corresponding one of the plurality of isolation openings 20a in the second isolation structure 22. At least a part of the touch component 60 is located on a side of the first electrode E1 away from the array substrate 10 and a side of the first virtual electrode C1 away from the array substrate 10.

The array substrate 10 includes a base 11 and the drive circuit layer 12 disposed on the base 11. The base 11 may be a hard base 11 that is made of glass, plastic or other materials. Alternatively, the base 11 may be a soft base 11 that is made of polyethersulfone (PES), polyacrylate (PAR), polyetherimide (PEI), polyethylene naphthalene dicarboxylate (PEN), polyethylene terephthalate (PET), polyphenylene sulfide (PPS), polyaromatic esters, polyimide (PI), polycarbonate (PC), cellulose acetate propionate (CAP), or other materials. A drive circuit that is configured to control the light-emitting structure 31 to emit light is disposed in the drive circuit layer 12. The drive circuit layer 12 is generally made of inorganic film layers, such as a metal layer, a semiconductor layer (an active layer), an insulating layer, and so on. The drive circuit that is configured to control the light-emitting structure 31 to emit light may be formed through framing these inorganic film layers. A specific circuit structure of the drive circuit may be realized in various ways, which will not be repeated herein.

At least one of the plurality of sub-pixels 30 may further include a second electrode E2. The second electrode E2, the light-emitting structure 31, and the first electrode E1 are stacked in sequence along a direction away from the array substrate 10. More than one first electrode E1 may be arranged in closely adjacent to form a layer, or the more than one first electrode E1 may be arranged at intervals. A thin film transistor TFT is disposed in the drive circuit layer 12 of the array substrate 10 and the second electrode E2 is electrically connected to the thin film transistor TFT. In response to the second electrode E2 and the first electrode E1 being energized, the second electrode E2 is configured to be an anode, the first electrode E1 is configured to be a cathode, and the thin film transistor TFT is configured to drive the light-emitting structure 31 to emit light.

The light-emitting structure 31 may be formed of multiple film layer structures stacked on top of one another. For example, the light-emitting structure 31 may include a hole injection layer (HIL), a hole transport layer (HTL), a light-emitting layer, an electron injection layer (EIL), and an electron transport layer (ETL) stacked on top of one another.

In some embodiments, the display panel 100 further includes a pixel defining layer 50 disposed on a side of the array substrate 10. The pixel defining layer 50 includes a pixel defining portion 51 and a pixel opening 52 encircled by the pixel defining portion 51. The light-emitting structure 31 and the virtual light-emitting portion 41 are disposed in the pixel opening 52 respectively, i.e., the light-emitting structure 31 and the virtual light-emitting portion 41 may not be disposed in the same pixel opening 52. The isolation structure 20 is located on a side of the pixel defining portion 51 away from the substrate. The display area AA may refer to an area that is able to display and the plurality of sub-pixels 30 are disposed in the display area AA. The non-display area NA may refer to an area that is unable to display. The non-display NA is generally configured to include wiring or to arrange a camera, a binding terminal, a test terminal, and so on. For example, the non-display area NA may be disposed around a periphery of the display area AA as an outer frame of the display panel 100; the non-display area NA may further be encircled by the display area AA as an area corresponding to the camera on the display panel 100.

The isolation structure 20 may be a structure that is wide at the top and narrow at the bottom or a structure in which a side wall thereof is recessed inwardly, as long as a continuous deposition of an evaporation material is not allowed on the side wall of the isolation structure 20. For example, a longitudinal section of the isolation structure 20 may be an inverted trapezoidal structure, a X-shaped structure, a T-shaped structure, or an I-shaped structure.

The isolation structure 20 may extend to the non-display area NA and therefore include the first isolation structure 21 and the second isolation structure 22. The non-display area NA includes a first sub-area NA3. A part of the isolation structure 20 in the display area AA is the first isolation structure 21 and a part of the isolation structure 20 in the first sub-area NA3 is the second isolation structure 21. The plurality of isolation openings 20a are defined on the isolation structure 20 and the light-emitting structure 31 is located in the plurality of isolation openings 20a in the first isolation structure 21. Each of the plurality of isolation openings 20a encircled by the first isolation structure 21 may correspond to one light-emitting structure 31. Alternatively, each of the plurality of isolation openings 20a encircled by the first isolation structure 21 may correspond to more than one light-emitting structure 31, i.e., more than one light-emitting structure 31 may be disposed in each of the plurality of isolation openings 20a encircled by the first isolation structure 21. Similarly, the virtual light-emitting portion 41 is located in the plurality of isolation openings 20a in the second isolation structure 22. Each of the plurality of isolation openings 20a encircled by the second isolation structure 22 may correspond to one virtual light-emitting portion 41. Alternatively, each of the plurality of isolation openings 20a encircled by the second isolation structure 22 may correspond to more than one virtual light-emitting portion 41, i.e., more than one virtual light-emitting portion 41 may be disposed in each of the plurality of isolation openings 20a encircled by the second isolation structure 22.

In some embodiments, during a preparation process of the display panel 100, the isolation structure 20 may generally be formed first and then the light-emitting structure 31 may be directly evaporated without the need of a mask plate. During the process, because of the presence of the isolation structure 20, some light-emitting materials may be evaporated in the plurality of isolation openings 20a and other light-emitting materials may be evaporated on a side of the isolation structure 20 away from the array substrate 10, thus light-emitting materials located on different sides of the isolation structure 20 along a direction parallel to a plane in which the array substrate 10 is located on are not continuous and each light-emitting structure 31 may be spaced apart without the need of the mask plate. Since the precise mask plate is not required for the evaporation of light-emitting structure 31, a cost of production and a precision requirement of the mask plate may be reduced, a shadow effect caused by using the precise mask plate in the evaporation of the light-emitting layer may be avoided, and a space between adjacent two of the plurality of sub-pixels 30 may be reduced, thereby increasing a brightness of the display panel 100. Moreover, since the ETL, the EIL, the HTL, the HIL, and etc. of the plurality of light emitting structures 31 are separated by the isolation structure 20, a crosstalk between adjacent two of the plurality of sub-pixels 30 may be avoided, thereby improving a display effect of the display panel 100. The plurality of virtual pixels 40 and the plurality of sub-pixels 30 may be prepared during a same preparation process so that the mask plate is not required, thereby simplifying a preparation method of the display panel 100 and improving an efficiency of preparing the display panel 100. During a preparation of the light-emitting structure 31, the light-emitting materials deposited in the plurality of isolation openings 20a in the second isolation structure 22 form the virtual light-emitting portion 41 so that removing the virtual light-emitting portion 41 separately by means of etching and other methods is no longer required, thereby simplifying the preparation method and improving the production efficiency.

The second isolation structure 22 and the plurality of virtual pixels 40 may shield a signal between the touch component 60 and the array substrate 10 in the non-display area NA, thereby eliminating an interference to a touch signal. In addition, the plurality of isolation openings 20a defined on the second isolation structure 22 may further be configured to fully release remaining moisture from a lower film layer before the evaporation in order to avoid separating the film layer structures as a result of a swelling deformation caused by the moisture, thereby improving the performance of the display panel 100.

In some embodiments, the first isolation structure 21 includes a conductive material and the first isolation structure 21 is connected to a first voltage power supply signal line of the display panel 100.

Each first electrode E1 is electrically connected through the first isolation structure 21 so that each first electrode E1 is electrically connected to the first voltage power supply signal line through the first isolation structure 21. For example, the first electrode E1 is a cathode so that the first voltage power supply signal line is a Vss signal line connected to a Vss bonding pad. The Vss bonding pad may be connected to a Vss pin on a drive chip through a flexible circuit board in order to receive a negative voltage power supply signal provided by the drive chip. Since the first electrode E1 of at least one of the plurality of sub-pixels 30 is connected to the first voltage power supply signal line of the display panel 100, the first electrode E1 may additionally shield the signal between the touch component 60 and the array substrate 10, in conjunction with the first isolation structure 21, to further reduce the interference to the touch signal, thereby improving the performance of the display panel 100.

In some embodiments, the second isolation structure 22 includes a conductive material and the first virtual electrode C1 is connected to the conductive material in the second isolation structure 22. Each first virtual electrode C1 may be electrically connected through the second isolation structure 22 to entirely form an electrode layer, thereby improving a shield effect to the touch component 60.

In some embodiments, the second isolation structure 22 is electrically connected to the first voltage power supply signal line. In specific, the first isolation structure 21 is electrically connected to the second isolation structure 22 and the second isolation structure 22 is electrically connected to the first voltage power supply signal line through the first isolation structure 21.

Each first virtual electrode C1 is electrically connected through the second isolation structure 22 so that each first virtual electrode C1 may be electrically connected to the first voltage power supply signal line through the second isolation structure 22 and the first isolation structure 21. Since the first virtual electrode C1 of at least one of the plurality of virtual pixels 40 is connected to the first voltage power supply signal line of the display panel 100, the first virtual electrode C1 may additionally shield the signal between the touch component 60 and the array substrate 10, in conjunction with the second isolation structure 22, to further reduce the interference to the touch signal, thereby improving the performance of the display panel 100. The first electrode E1 and the first virtual electrode C1 are connected to a same voltage power supply signal line, through the isolation structure 20, to form potentials in a plane to shield the touch signal and a drive signal, thereby further improving the shield effect. Moreover, the embodiments of the present disclosure may not require the second isolation structure 22 to be electrically connected to the first voltage power supply signal line in separate, thereby further reducing the cost.

In some embodiments, the first isolation structure 21 is insulated from the second isolation structure 22 and the second isolation structure 22 is connected to the first voltage power supply signal line. The first isolation structure 21 and the second isolation structure 22 are connected to the first voltage signal line individually, thereby reducing the signal crosswalk.

As illustrated in FIG. 6, in some embodiments, at least one of the plurality of sub-pixels 30 further include the second electrode E2. The second electrode E2, the light-emitting structure 31, and the first electrode E1 are staked in sequence along the direction away from the array substrate 10. The thin film transistor TFT is disposed in the drive circuit layer 12 of the array substrate 10. The second electrode E2 is electrically connected to the thin film transistor TFT so that the second electrode E2 is connected to a second voltage power supply signal line through the thin film transistor TFT. For example, the second voltage power supply signal line is a voltage drain drain (VDD) signal line. In response to the second electrode E2 and the first electrode E1 being energized, the second electrode E2 is configured to be an anode, the first electrode E1 is configured to be a cathode, and the plurality of sub-pixels 30 are able to emit light. A second virtual electrode C2 is not required to be disposed in at least one of the plurality of virtual pixels 40, and in this case, at least one of the plurality of virtual pixels 40 may be only formed by the virtual light-emitting portion 41 and the first virtual electrode C1, thus the plurality of virtual pixels 40 may not emit light.

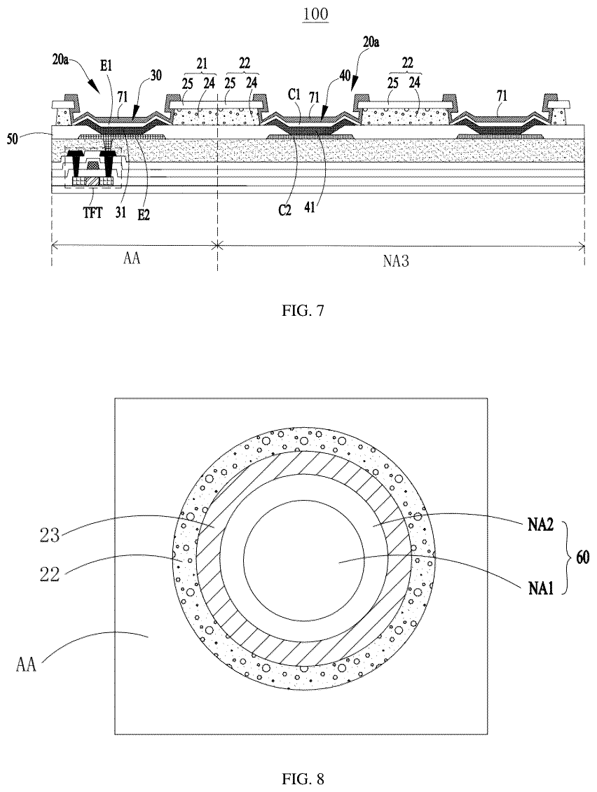

As illustrated in FIG. 7, in some embodiments, at least one of the plurality of virtual pixels 40 may further include the second virtual electrode C2. The second virtual electrode C2, the virtual light-emitting portion 41, and the first virtual electrode C1 are stacked in sequence along the direction away from array substrate 10. Compared the second electrode E2 with the second virtual electrode C2, the second voltage power supply signal line of the display panel 100 is only electrically connected to the second electrode E2.

The second electrode E2 is connected to the second voltage power supply signal line of the display panel 100 and the second virtual electrode C2 is not connected to the second voltage power supply signal line. Since the second electrode E2 is connected to an electrical signal but the second virtual electrode C2 is not connected to the electrical signal, the plurality of sub-pixels 30 is able to emit light but the plurality of virtual pixels 40 is not able to emit light.

In some embodiments, the second electrode E2 and the second virtual electrode C2 may be disposed on a same layer, may include a same material, and may be prepared during a same process. The light-emitting structure 31 and the virtual light-emitting portion 41 may be disposed on a same layer, may include a same material, and may be prepared during a same process. The second virtual electrode C2 is not connected to the thin film transistor TFT of the array substrate 10 so the plurality of virtual pixels 40 is not able to emit light. That is, the plurality of virtual pixels 40 and the plurality of sub-pixels 30 share a same structure and a same preparation method, but the only difference is that the plurality of virtual pixels 40 are not connected to the drive circuit.

As illustrated in FIG. 1 and FIG. 8, in some embodiments, the display area AA is disposed around at least a part of a periphery of the non-display area NA, the non-display area NA includes a light-transmitting aperture NA1 and an aperture bezel area NA2 disposed around a periphery of the light-transmitting aperture NA1, and the plurality of virtual pixels 40 are arranged in the aperture bezel area NA2.

The non-display area NA and the camera are arranged correspondingly along a direction perpendicular to the array substrate 10. The light-transmitting aperture NA1 is configured to allow external light to pass through and reach the camera. Since the plurality of virtual pixels 40 are arranged in aperture bezel area NA2, the plurality of virtual pixels 40 and the second isolation structure 22 may reduce an interference by the drive signal of the array substrate 10 to the touch signal of the touch component 60 located above.

As illustrated in FIG. 8, in some embodiments, the second isolation structure 22 is disposed around the periphery of the light-transmitting aperture NA1. The second isolation structure 22 is arranged in an annular shape and the plurality of virtual pixels 40 are arranged at intervals around the light-transmitting aperture NA1, in order to further shield the signal between the array substrate 10 and the touch component 60 in the aperture bezel area NA2.

In some embodiments, a first space is defined between the second isolation structure 22 and an edge of the light-transmitting aperture NA1. In other words, the second isolation structure 22 is a certain distance away from the edge of the light-transmitting aperture NA1 in order to avoid moisture entering the plurality of virtual pixels 40 and further the plurality of sub-pixels 30, to affect a light-emitting efficiency of the light-emitting structure 31.

In some embodiments, the non-display area NA includes a display bezel area NA5 and the display bezel area NA5 is disposed around the periphery of the display area AA. For example, the display bezel area NA5 may be disposed on top, bottom, left, and right sides of the display area AA. Since the plurality of virtual pixels 40 are arranged in the non-display area NA, the plurality of virtual pixels 40 and the second isolation structure 22 may reduce the interference by the drive signal of the array substrate 10 to the touch signal of the touch component 60 located above.

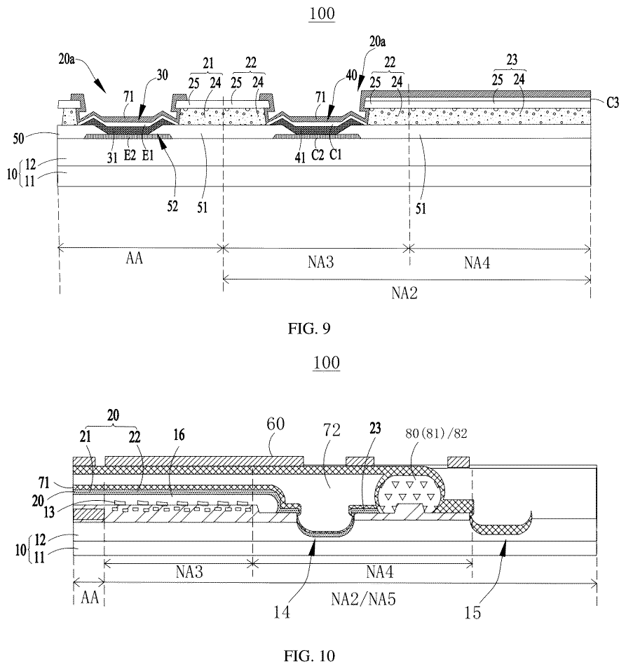

As illustrated in FIG. 2, FIG. 8, and FIG. 9, in some embodiments, the display panel further includes a shielding structure 23 disposed in the aperture bezel area NA2. The shielding structure 23 is disposed on a side of the second isolation structure 22 away from the first isolation structure 21 along a direction parallel to the array substrate 10. The shielding structure 23 may be configured to shield the signal to the touch component 60 located above, thereby further reducing the signal interference to the touch component 60.

In some embodiments, the plurality of isolation openings 20a are only defined on the first isolation structure 21 and the second isolation structure 22. The plurality of isolation openings 20a are not defined on the shielding structure 23. Since the shielding structure 23 is closer to the light-transmitting aperture NA1 compared to the second isolation structure 22, the plurality of isolation openings 20a are not defined on shielding structure 23, thereby further avoiding the moisture entering the display area AA.

In some embodiments, a third virtual electrode C3 is disposed on a side of the shielding structure 23 away from the array substrate 10. The third virtual electrode C3 and the first virtual electrode C1 are disposed on a same layer. The shielding structure 23 and the third virtual electrode C3 disposed on the shielding structure 23 may further reduce the interference by the drive signal to the touch signal of the touch component 60 located above. The third virtual electrode C3 and the first virtual electrode C1 are prepared during a same process, thereby improving the preparation efficiency.

In some embodiments, an orthographic projection of an outer contour of the touch component 60 on the array substrate 10 is located within an orthographic projection of an outer contour of the shielding structure 23 on the array substrate 10.

The touch component 60 may include a touch electrode and some signal lines connected to the touch electrode, such as a touch ground signal line, a touch drive signal line, a touch receive signal line, and so on. An outermost side of the touch component 60 along the direction parallel to the array substrate 10 is the outer contour of the touch component 60. An outermost side of the shielding structure 23 along the direction parallel to the array substrate 10 is the outer contour of the shielding structure 23. The orthographic projection of the outer contour of the touch component 60 on the array substrate 10 is arranged within the orthographic projection of the outer contour of the shielding structure 23 on the array substrate 10 so that an outer portion of the touch component 60 may be completely covered by the shielding structure 23. The shielding structure 23 may reduce a touch RF interference and therefore further improve the performance of the display panel 100.

In some embodiments, the non-display area NA includes the light-transmitting aperture NA1 and the aperture bezel area NA2 disposed around the periphery of the light-transmitting aperture NA1. The shielding structure 23 is located in the aperture bezel area NA2 and is disposed around the periphery of the light-transmitting aperture NA1. The shielding structure 23 is arranged in an annular shape around the periphery of the light-transmitting aperture NA1, thereby avoiding the moisture entering the display area AA from all directions in a comprehensive manner.

In some embodiments, the second isolation structure 22 is disposed around a periphery of the shielding structure 23. The second isolation structure 22 is disposed in the aperture bezel area NA2 and is arranged in an annular shape, thereby further shielding the signal between the array substrate 10 and the touch component 60 in the aperture bezel area NA2.

In some embodiments, a second space is defined between the shielding structure 23 and the edge of the light-transmitting aperture NA1. The shielding structure 23 is a certain distance away from the edge of the light-transmitting aperture NA1 in order to avoid the shielding structure 23 being cut when the light-transmitting aperture NA1 is formed by cutting. After a crack is formed, the moisture may enter the display area AA through the crack on the isolation structure 20.

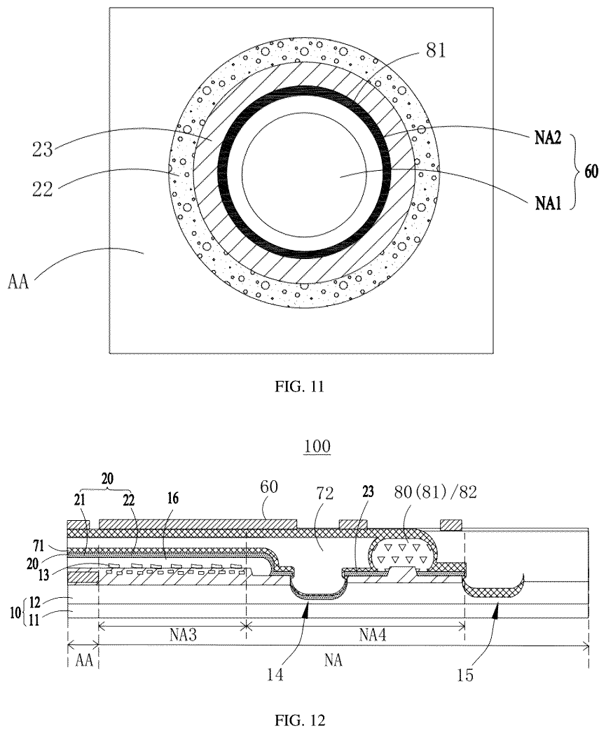

As illustrated in FIG. 10 and FIG. 11, in some embodiments, the display panel 100 further includes a first bank 81. The first bank 81 is located in the aperture bezel area NA2 and is disposed around the periphery of the light-transmitting aperture NA1. The orthographic projection of the shielding structure 23 on the array substrate 10 is located outside an area encircled by the first bank 81. The first bank 81 is disposed around a periphery of the second encapsulation layer 72. The first bank 81 is arranged so that the second encapsulation layer 72 may be bounded in the first bank 81, thereby avoiding an encapsulation material of the second encapsulation layer 72 flowing outward. “The orthographic projection of the shielding structure 23 on the array substrate 10 is located outside an area encircled by the first bank 81” means that the shielding structure 23 is bounded in the first bank 81 so that the shielding structure 23 may be protected from the top by the first encapsulation layer 71, the second encapsulation layer 72, and other multiple encapsulation thin film layers, thereby improving a reliability of the display panel.

In some embodiments, as illustrated in FIG. 12, a part of the orthographic projection of the shielding structure 23 on the array substrate 10 is located within the area encircled by the first bank 81. That is, a part of the shielding structure 23 is located below the first bank 81 and the other part of the shielding structure 23 is bounded in the first bank 81, thereby further protecting the shielding structure 23 to some extent and improving the reliability of the display panel.

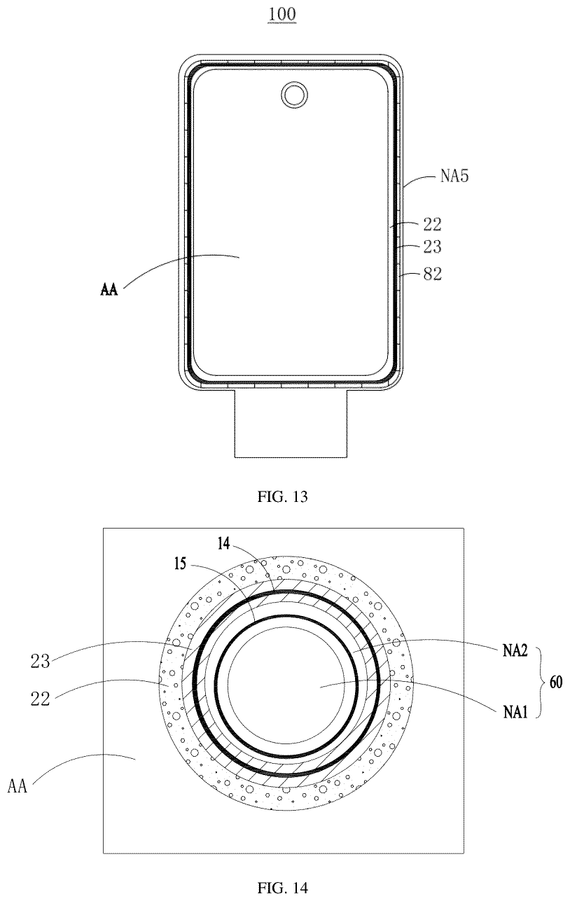

As illustrated in FIG. 10 and FIG. 13, in some embodiments, the non-display area NA includes the display bezel area NA5 of the display panel 100, the display bezel area NA5 is disposed around the periphery of the display area AA, and the shielding structure 23 is located in the display bezel area NA5 and is disposed around the periphery of the second isolation structure 22.

In some embodiments, the display panel 100 further includes a second bank 82, the second bank 82 is located in the display bezel area NA5 and is disposed around the periphery of the display area AA. The orthographic projection of the shielding structure 23 on the array substrate 10 is located within an area encircled by the second bank 82. The second bank 82 is arranged so that the second encapsulation layer 72 may be bounded in the second bank 82, thereby avoiding an encapsulation material of the second encapsulation layer 72 flowing outward. “The orthographic projection of the shielding structure 23 on the array substrate 10 is located outside an area encircled by the second bank 82” means that the shielding structure 23 is bounded in the second bank 82, and thus the shielding structure 23 may be protected from the top by the first encapsulation layer 71, the second encapsulation layer 72, and other multiple encapsulation thin film layers, thereby improving the reliability of the display panel.

In some embodiments, as illustrated in FIG. 12, a part of the orthographic projection of the shielding structure 23 on the array substrate 10 is located outside the area encircled by the second bank 82. That is, a part of the shielding structure 23 is located below the second bank 82 and the other part of the shielding structure 23 is restricted outside of the second bank 82, thereby further protecting the shielding structure 23 to some extent and improving the reliability of the display panel.

In some embodiments, the first isolation structure 21, the second isolation structure 22, and the shielding structure 23 are disposed on a same layer. The second isolation structure 22 and the shielding structure 23 may be prepared during a same process, but a shape of the second isolation structure 22 is different from a shape of the shielding structure 23. When the plurality of isolation openings 20a are defined on the second isolation structure 22 through an exposure and development method, the plurality of isolation openings 20a are not defined on the shielding structure 23. For example, the first isolation structure 21, the second isolation structure 22, and the shielding structure 23 are disposed on the same layer and are prepared during the same process. The aperture bezel area NA2 is formed by the first sub-area NA3 and a second sub-area NA4. An isolation structure located in the display area AA is the first isolation structure 21, an isolation structure located in the first sub-area NA3 is the second isolation structure 22, and an isolation structure located in the second sub-area NA4 is the shielding structure 23. The embodiments of the present disclosure may improve the preparation efficiency of the display panel 100.

As illustrated in FIG. 10 and FIG. 14, in some embodiments, a first recess 14 is defined on the array substrate 10 in the non-display area NA, an orthographic projection of the first recess 14 on the array substrate 10 is located within the orthographic projection of the shielding structure 23 on the array substrate 10. For example, the first recess 14 is a curve so a part of the shielding structure 23 in the first recess 14 is a curve. The first recess 14 is arranged so that a length of the shielding structure 23 may be extended and thus a path in which the moisture enters the display area AA may be extended.

In some embodiments, a second recess 15 is defined on the array substrate 10 in the non-display area NA and the second recess 15 is farther from the display area AA compared to the first recess 14. Through additionally arranging the second recess 15, the path in which the moisture enters the display area AA may be further extended.

In some embodiments, an orthographic projection of the second recess 15 on the array substrate 10 is located outside the orthographic projection of the shielding structure 23 on the array substrate 10. That is, the second recess 15 is defined relatively close to the edge of the light-transmitting aperture NA1 and the shielding structure 23 is not disposed in the second recess 15, thereby avoiding the moisture entering the shielding structure 23 to some extent and further reducing a possibility of the moisture entering the display area AA from the shielding structure 23.

From a top view of the display panel 100, each of the first recess 14 and the second recess 15 may be arranged in an annular shape in order to further reduce the possibility of the moisture entering the display area AA.

In some embodiments, the array substrate 10 includes the base 11 and the drive circuit layer 12 disposed on a side of the base 11. The drive circuit layer 12 includes a drive circuit line 13. An orthographic projection of the drive circuit line 13 on the base 11 at least partially overlaps an orthographic projection of the plurality of virtual pixels 40 on the base 11.

The drive circuit line 13 may be a data line, a gate in panel (GIP) wiring, and so on. The orthographic projection of the drive circuit line 13 on the base 11 at least partially overlaps the orthographic projection of the plurality of virtual pixels 40 on the base 11, an orthographic projection of the touch component 60 on the base 11 at least partially overlaps the orthographic projection of the plurality of virtual pixels 40 on the base 11, the plurality of virtual pixels 40 are disposed between the touch component 60 and the drive circuit line 13, thereby shielding a signal interference by the drive circuit line 13 to the touch component 60.

In some embodiments, the orthographic projection of the drive circuit line 13 on the base 11 is located within orthographic projections of the plurality of virtual pixels 40 and the second isolation structure 22 on the base 11. The plurality of virtual pixels 40 and the second isolation structure 22 cover the drive circuit line 13, thereby reducing the interference by the drive circuit line 13 to the touch signal to a maximum extent.

In some embodiments, the display panel 100 further includes the shielding structure 23 located in the non-display area NA. The shielding structure 23 is disposed on a side of the second isolation structure 22 away from the first isolation structure 21 along the direction parallel to the array substrate 10. The drive circuit line 13 is disposed in an area of the array substrate 10 corresponding to the second isolation structure 22.

The shielding structure 23 is configured to shield the signal to the touch component 60 located above, thereby further reducing the signal interference to the touch component 60. The second isolation structure 22 is disposed between the touch component 60 and the drive circuit line 13 so that the signal interference by the drive circuit line 13 to the touch component 60 is guaranteed to be shielded.

In some embodiments, the plurality of isolation openings 20a are only defined on the first isolation structure 21 and the second isolation structure 22. The plurality of isolation openings 20a are not defined on the shielding structure 23.

That is, the shielding structure 23 is arranged in a manner that the drive circuit line 13 is not disposed below the shielding structure 23 but the touch component 60 is disposed above the shielding structure 23. Since the shielding structure 23 is disposed relatively close to the light-transmitting aperture NA1, the plurality of isolation openings 20a are not defined on the shielding structure 23 so as to avoid the moisture entering the display area AA.

In some embodiments, the orthographic projection of the shielding structure 23 on the array substrate 10 is located outside the orthographic projection of the drive circuit line 13 on the array substrate 10. The drive circuit line 13 is not disposed in an area corresponding to the shielding structure 23 on the array substrate 10 and since neither the drive circuit line 13 nor a planarization layer 16 is disposed in the area, there is no risk of the drive circuit line 13 and the planarization layer 16 detaching from each other and the cost may be reduced because the plurality of isolation openings 20a are not required to be arranged to release moisture from the planarization layer 16.

In some embodiments, the third virtual electrode C3 is disposed on the side of the shielding structure 23 away from the array substrate 10 and the virtual electrode C3 and the first virtual electrode C1 are disposed on a same layer, thereby reducing the signal interference from the drive circuit line 13 to the touch component 60 located diagonally above.

In some embodiments, the first isolation structure 21 and the second isolation 22 are disposed on a same layer. The first isolation structure 21 and the second isolation 22 are prepared during the same preparation process and the shape of the second isolation structure 22 and the shape of the shielding structure 23 are the same.

In some embodiments, the first isolation structure 21, the second isolation 22, and the shielding structure 23 are disposed on a same layer and are prepared during the same preparation process. The shape of first isolation structure 21 and the shape of the second isolation 22 are the same. The plurality of isolation openings 20a are defined on both the first isolation structure 21 and the second isolation 22. The shape of the shielding structure 23 is different from the shape of the first isolation structure 21 and the shape of the second isolation 22. The plurality of isolation openings 20a are not defined on the shielding structure 23.

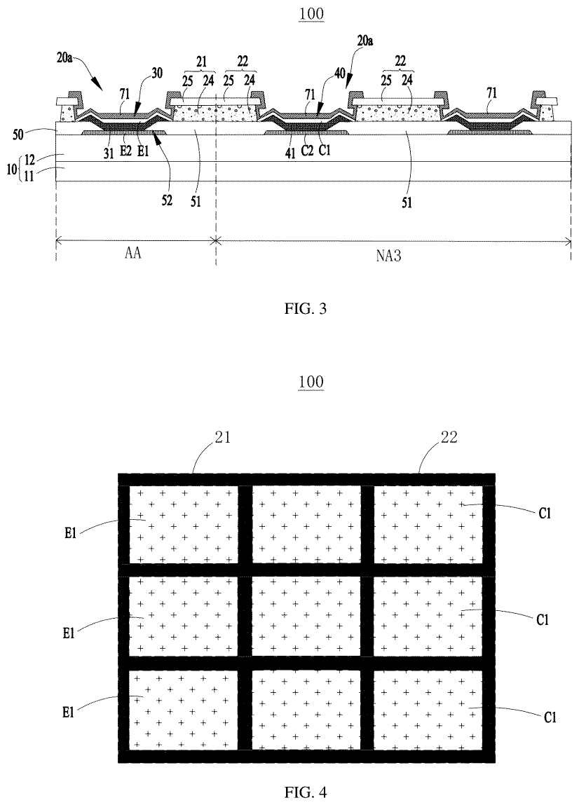

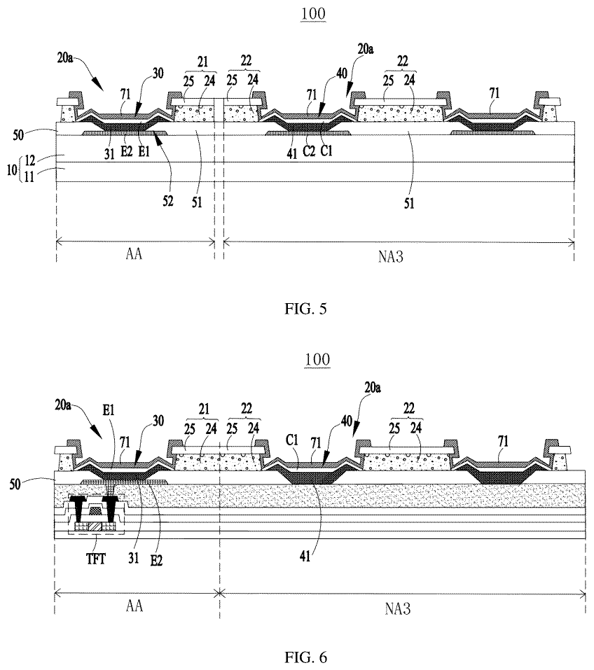

As illustrated in FIG. 3, in some embodiments, the first isolation structure 21 and the second insolation structure 22 both include a support layer 24 and a masking layer 25 stacked on the support layer 24 along the direction away from substrate. Adjacent light-emitting structures 31 may be further isolated because of the support layer 24 and the masking layer 25. The support layer 24 and the masking layer 25 may be prepared using different materials to satisfy different requirements.

In some embodiments, an orthographic projection of the support layer 24 on the array substrate 10 is located within an orthographic projection of the masking layer 25 on the array substrate 10 and an area of the orthographic projection of the support layer 24 on the array substrate 10 is less than an area of the orthographic projection of the masking layer 25 on the array substrate 10. An edge of the masking layer 25 extends from a periphery of the support layer 24 and the first electrode E1 is spaced apart by the support layer 24. The support layer 24 may be designed to be relatively high and the masking layer 25 may be designed to be relatively wide so that the longitudinal section of the isolation structure 20, as a combination of the support layer 24 and the masking layer 25, may be a T-shaped structure. Compared to an embodiment in which the isolation structure 20 is designed, as a whole, to be an inverted trapezoidal structure, the isolation structure 20 provided by the embodiments of the present disclosure is configured to isolate the first electrode E1 through reaching deeply into the first electrode E1 and the masking layer 25 located above may further enhance a reflection and refraction effect, thereby realizing a more distinctive and brighter display effect.

In some embodiments, along a direction perpendicular to and pointing to the substrate, a cross section area of the support layer 24 gradually increases. The support layer 24 may be made of a metal material and a shape of a longitudinal section of the support layer 24 may be a regular trapezoid. In this way, the support layer 24 may be easily prepared and a lapping effect of the first electrode E1 may be improved when the isolation structure 20 includes the conductive material to facilitate electrically connecting each first electrode E1 through the isolation structure 20 and further connecting each first electrode E1 to a same electrode power supply signal terminal, thereby simplifying the structure and reducing the cost.

In some embodiments, along the direction perpendicular to and pointing to the substrate, a cross section area of the masking layer 25 gradually increases, i.e., a shape of a longitudinal section of the masking layer 25 may be a regular trapezoid, thereby facilitating the preparation and reducing shielding an evaporation deposition of the first electrode E1.

As illustrated in FIG. 10, in some embodiments, the display panel 100 further includes the first encapsulation layer 71 and the first encapsulation layer 71 is disposed on the side of the isolation structure 20 away from the array substrate 10. The first encapsulation layer 71 may protect the plurality of sub-pixels 30 from being affected by external environment (e.g., moisture and air), avoid the moisture and the air permeating an interior of the display panel 100, and extend a service life and a reliability of the light-emitting structure 31. The encapsulation layer may further avoid impurities and harmful substances entering the display panel 100, thereby ensuring the performance and quality of the display panel 100.

In some embodiments, the first encapsulation layer 71 covers at least a part of the side wall of the isolation structure 20, thereby further protecting the isolation structure 20 and more effectively avoiding the harmful substances, e.g., external moisture and oxygen, entering an interior of the plurality of sub-pixels 30.

In some embodiments, the first encapsulation layer 71 includes an inorganic material. For example, the first encapsulation layer 71 may be made of silicon oxide, silicon nitride, silicon nitride oxide, and other materials, which may provide a good mechanical support and encapsulation protection to protect the display panel 100 from being affected by the environment. In addition, the first encapsulation layer 71 may further effectively insulate the display panel 100 from the external moisture and oxygen, and other harmful substances from entering the interior of the display panel 100, thereby improving the service life and stability of the display panel 100.

In some embodiments, the display panel 100 further includes the second encapsulation layer 72 and the second encapsulation layer 72 is disposed on a side of the first encapsulation layer 71 away from the array substrate 10. The second encapsulation layer 72 may further avoid the external moisture and oxygen, etc., entering the interior of the display panel 100.

In some embodiments, the second encapsulation layer 72 includes an organic material. The second encapsulation layer 72 may be made of polymers and organic materials. A thickness of the second encapsulation layer 72 is greater than a thickness of the first encapsulation layer 71 and the second encapsulation layer 72 is more flexible, so that the second encapsulation layer 72 may be better adapted to a bend and a curvature of the display panel 100. Moreover, the organic material may be configured to buffer against an external force.

In some embodiments, the display panel 80 further includes a bank 80. The bank 80 is disposed on the array substrate 10 and is located in the non-display area NA. The bank 80 is disposed around the periphery of the second encapsulation layer 72. The bank 80 is arranged so that the second encapsulation layer 72 may be bounded in the bank 80, thereby avoiding the encapsulation material of the second encapsulation layer 72 flowing outward.

In some embodiments, the non-display area NA includes the light-transmitting aperture NA1 and the aperture bezel area NA2 disposed around the periphery of the light-transmitting aperture NA1. The bank 80 includes the first bank 81, the first bank 81 is located in the aperture bezel area NA2 and is disposed around the periphery of the light-transmitting aperture NA1; and/or, the non-display area NA includes the display bezel area NA5 of the display panel 100, the display bezel area NA5 is disposed around the periphery of the display area AA, the bank 80 includes the second bank 82, the second bank 82 is located in the display bezel area NA5 and is disposed around the periphery of the display area AA.

In some embodiments, the orthographic projection of the second isolation structure 22 on the array substrate 10 is located within an orthographic projection of the bank 80 on the array substrate 10. The bank 80 is arranged outside of the second isolation structure 22 so that the orthographic projection of the second encapsulation layer 72 on the array substrate 10 covers the orthographic projection of the second isolation structure 22 on the array substrate 10, thereby further protecting the plurality of virtual pixels 40 and avoiding the moisture entering the display area AA from the plurality of virtual pixels 40 through the isolation structure 20.

A second aspect of the present disclosure provides a display device, and the display device includes the display panel 100 in any one of the embodiments mentioned above or the display panel 100 prepared by any one of the aforementioned preparation methods. Since the display device adopts all technical solutions mentioned in all the embodiments above, the display device is at least provided with all the benefits of the technical solutions mentioned in the embodiments above, which will not be repeated herein.

The display device may be any device with a display function, for example, a mobile device such as a cell phone, a tablet computer, a laptop computer, a palmtop computer, a vehicle-mounted electronic device, a wearable device, an ultra-mobile personal computer (UMPC), a netbook, a personal digital assistant (PDA) or other mobile devices; or a non-mobile device such as a personal computer (PC), a television (TV), a teller machine, a kiosk, or other non-mobile devices.

Despite the embodiments disclosed in the present disclosure are provided above, the described contents are only embodiments adopted for the purpose of facilitating the understanding of the present disclosure and are not intended to limit the present disclosure. Any ordinary skilled in the art to which the present disclosure belongs may, without departing from the spirit and scope of the disclosure of the present disclosure, make any modifications and changes in the form and details of the embodiments, but the scope of protection of the present disclosure shall still be subject to the scope defined in the appended claims.

The above description are only specific embodiments of the present disclosure, and it should be clearly understood by the ordinary skilled in the art to which the present disclosure belongs that, for the convenience and brevity of the description, the substitution of other connection methods and the like as described above can be referred to the corresponding process in the foregoing embodiments of the method, which will not be repeated herein. It should be understood that the scope of protection of the present disclosure is not limited thereto, and any ordinary skilled in the art can easily come up with various equivalent modifications or substitutions within the scope of the technology disclosed in the present disclosure, which shall be covered by the scope of protection of the present disclosure.

1. A display panel with a display area and a non-display area, comprising:
an array substrate, comprising a drive circuit layer;
an isolation structure, comprising a first isolation structure in the display area and a second isolation structure in the non-display area; wherein the first isolation structure and the second isolation structure are both disposed on a side of the array substrate; and a plurality of isolation openings are defined on the first isolation structure and the second isolation structure;
a plurality of sub-pixels and a plurality of virtual pixels; wherein at least one of the plurality of sub-pixels is located in the display area and comprises a light-emitting structure and a first electrode stacked on the light-emitting structure; the light-emitting structure is located in a corresponding one of the plurality of isolation openings in the first isolation structure; and at least one of the plurality of virtual pixels is located in the non-display area and comprises a first virtual electrode; and
a touch component, wherein at least a part of the touch component is located on a side of the first electrode away from the array substrate and a side of the first virtual electrode away from the array substrate.

2. The display panel as claimed in claim 1, wherein the second isolation structure comprises a conductive material, the first virtual electrode is connected to the conductive material of the second isolation structure, and the second isolation structure is electrically connected to a first voltage power supply signal line of the display panel.

3. The display panel as claimed in claim 2, wherein the first isolation structure comprises a conductive material, the first isolation structure is electrically connected to the second isolation structure, and the second isolation structure is electrically connected to the first voltage power supply signal line through the first isolation structure; or
the first isolation structure is insulated from the second isolation structure, and the second isolation structure is electrically connected to the first voltage power supply signal line.

4. The display panel as claimed in claim 1, wherein at least one of the plurality of virtual pixels further comprises a virtual light-emitting portion that is located in a corresponding one of the plurality of isolation openings in the second isolation structure and the virtual light-emitting portion is located at a side of the first virtual electrode close to the array substrate; and
at least one of the plurality of sub-pixels further comprises a second electrode; the second electrode, the light-emitting structure, and the first electrode are stacked in sequence along a direction away from the array substrate.

5. The display panel as claimed in claim 4, wherein at least one of the plurality of virtual pixels further comprises a second virtual electrode; the second virtual electrode, the virtual light-emitting portion, and the first virtual electrode are stacked in sequence along the direction away from the array substrate; and
in the second electrode and the second virtual electrode, a second voltage power supply signal line of the display panel is only electrically connected to the second electrode; and
the first electrode and the first virtual electrode are disposed on a same layer.

6. The display panel as claimed in claim 1, wherein the non-display area comprises a light-transmitting aperture and an aperture bezel area disposed around a periphery of the light-transmitting aperture; the display area is disposed around at least a part of a periphery of the aperture bezel area, and the plurality of virtual pixels are located in the aperture bezel area; or
the non-display area comprises a display bezel area of the display panel, the display bezel area is disposed around a periphery of the display area, and the plurality of virtual pixels are located in the display bezel area of the display panel.

7. The display panel as claimed in claim 6, wherein the second isolation structure is disposed around the periphery of the light-transmitting aperture; and
a first space is defined between the second isolation structure and an edge of the light-transmitting aperture.

8. The display panel as claimed in claim 1, wherein the display panel comprises a shielding structure in the non-display area and along a direction parallel to the array substrate, the shielding structure is disposed on a side of the second isolation structure away from the first isolation structure.

9. The display panel as claimed in claim 8, wherein the plurality of isolation openings are only defined on the first isolation structure and the second isolation structure; and
a third virtual electrode is disposed on a side of the shielding structure away from the array substrate; and the third virtual electrode and the first virtual electrode are disposed on a same layer; and
an orthographic projection of an outer contour of the touch component on the array substrate is located within an orthographic projection of an outer contour of the shielding structure on the array substrate; and
the non-display area comprises a light-transmitting aperture and an aperture bezel area disposed around a periphery of the light-transmitting aperture; the shielding structure is located in the aperture bezel area and is disposed around the periphery of the light-transmitting aperture; and
the second isolation structure is disposed around a periphery of the shielding structure; and
a second space is defined between the shielding structure and an edge of the light-transmitting aperture; and
the display panel further comprises a first bank, the first bank is located in the aperture bezel area and is disposed around the periphery of the light-transmitting aperture, an orthographic projection of the shielding structure on the array substrate is located outside an area encircled by the first bank; or a part of the orthographic projection of the shielding structure on the array substrate is located within the area encircled by the first bank; and
the non-display area comprises a display bezel area of the display panel, the display bezel area is disposed around a periphery of the display area, the shielding structure is located in the display bezel area and is disposed around a periphery of the second isolation structure; and
the display panel further comprises a second bank, the second bank is located in the display bezel area and is disposed around the periphery of the display area, the orthographic projection of the shielding structure on the array substrate is located within an area encircled by the second bank; or a part of the orthographic projection of the shielding structure on the array substrate is located outside the area encircled by the second bank; and
the first isolation structure, the second isolation structure, and the shielding structure are disposed on a same layer.

10. The display panel as claimed in claim 9, wherein a first recess is defined on the array substrate in the non-display area, and an orthographic projection of the first recess on the array substrate is located within the orthographic projection of the shielding structure on the array substrate.

11. The display panel as claimed in claim 10, wherein a second recess is defined on the array substrate in the non-display area and the second recess is farther from the display area compared to the first recess; and
an orthographic projection of the second recess on the array substrate is located outside the orthographic projection of the shielding structure on the array substrate.

12. The display panel as claimed in claim 1, wherein the array substrate further comprises a base, and the drive circuit layer is disposed on a side of the base; the drive circuit layer comprises a drive circuit line, and an orthographic projection of the drive circuit line on the base at least partially overlaps an orthographic projection of the plurality of virtual pixels on the base.

13. The display panel as claimed in claim 12, wherein the orthographic projection of the drive circuit line on the base is located within the orthographic projection of the plurality of virtual pixels on the base and an orthographic projection of the second isolation structure on the base; and
the display panel further comprises a shielding structure located in the non-display area, the shielding structure is disposed on a side of the second isolation structure away from the first isolation structure along a direction parallel to the array substrate, and the drive circuit line is disposed in an area of the array substrate corresponding to the second isolation structure; and
the plurality of isolation openings are only defined on the first isolation structure and the second isolation structure; and
an orthographic projection of the shielding structure on the array substrate is located outside the orthographic projection of the drive circuit line on the array substrate.

14. The display panel as claimed in claim 1, wherein the first isolation structure and the second isolation are disposed on a same layer.

15. The display panel as claimed in claim 14, wherein the first isolation structure and the second insolation structure comprises a support layer and a masking layer stacked on the support layer along a direction away from substrate; and
an orthographic projection of the support layer on the array substrate is located within an orthographic projection of the masking layer on the array substrate; and an area of the orthographic projection of the support layer on the array substrate is less than an area of the orthographic projection of the masking layer on the array substrate; and
along a direction perpendicular to and pointing to the substrate, a cross section area of the support layer gradually increases; and
along the direction perpendicular to and pointing to the substrate, a cross section area of the masking layer gradually increases.

16. The display panel as claimed in claim 1, wherein the display panel further comprises a first encapsulation layer, and the first encapsulation layer is disposed on a side of the isolation structure away from the array substrate.

17. The display panel as claimed in claim 16, wherein the first encapsulation layer covers at least a part of a side wall of the isolation structure; and
the first encapsulation layer comprises an inorganic material; and
the display panel further comprises a second encapsulation layer, and the second encapsulation layer is disposed on a side of the first encapsulation layer away from the array substrate; and
the second encapsulation layer comprises an organic material; and
the display panel further comprises a bank, the bank is disposed on the array substrate and is located in the non-display area, and the bank is disposed around a periphery of the second encapsulation layer.

18. The display panel as claimed in claim 17, wherein the non-display area comprises a light-transmitting aperture and an aperture bezel area disposed around a periphery of the light-transmitting aperture; the bank comprises a first bank, the first bank is located in the aperture bezel area and is disposed around the periphery of the light-transmitting aperture; and
the non-display area comprises a display bezel area of the display panel, the display bezel area is disposed around a periphery of the display area; the bank comprises a second bank, the second bank is located in the display bezel area and is disposed around the periphery of the display area.

19. The display panel as claimed in claim 18, wherein an orthographic projection of the second isolation structure on the array substrate is located within an orthographic projection of the second bank on the array substrate.

20. A display device, comprising a display panel, the display panel having a display area and a non-display area, comprising:
an array substrate, comprising a drive circuit layer;
an isolation structure, comprising a first isolation structure in the display area and a second isolation structure in the non-display area; wherein the first isolation structure and the second isolation structure are both disposed on a side of the array substrate; and a plurality of isolation openings are defined on the first isolation structure and the second isolation structure;
a plurality of sub-pixels and a plurality of virtual pixels; wherein at least one of the plurality of sub-pixels is located in the display area and comprises a light-emitting structure and a first electrode stacked on the light-emitting structure; the light-emitting structure is located in a corresponding one of the plurality of isolation openings in the first isolation structure; and at least one of the plurality of virtual pixels is located in the non-display area and comprises a first virtual electrode; and
a touch component, wherein at least a part of the touch component is located on a side of the first electrode away from the array substrate and a side of the first virtual electrode away from the array substrate.
